(19) United States
(12) Patent Application Publication
(10) Pub. No.: US 2018/0014431 A1
(43) Pub. Date: Jan. 11, 2018

(54) Thermal Pad and Electronic Device

(71) Applicant: Huawei Technologies Co., Ltd., Shenzhen (CN)

(72) Inventors: Yan Xu, Yokohama (JP); Renzhe Zhao, Shenzhen (CN)

(21) Appl. No.: 15/696,496

(22) Filed: Sep. 6, 2017

Related U.S. Application Data
(63) Continuation of application No. PCT/CN2016/073612, filed on Feb. 5, 2016.

(30) Foreign Application Priority Data
Jun. 29, 2015 (CN) 201510368581.9

(51) Int. Cl. H05K 7/20; H01L 23/373; H01L 23/367

(52) U.S. Cl. CPC H05K 7/20509; H01L 23/3737; H01L 23/3735; H01L 23/367

(57) ABSTRACT

A thermal pad and an electronic device comprising the thermal pad includes a first heat conducting layer and a second heat conducting layer. The first heat conducting layer is deformable under compression, and a heat conduction capability of the first heat conducting layer in a thickness direction of the first heat conducting layer is greater than a heat conduction capability of the first heat conducting layer in a plane direction of the first heat conducting layer. The second heat conducting layer is not deformable under compression, and a heat conduction capability of the second heat conducting layer in a plane direction of the second heat conducting layer is greater than or equal to a heat conduction capability of the second heat conducting layer in a thickness direction of the second heat conducting layer.

### CROSS-REFERENCE TO RELATED APPLICATIONS

This application is a continuation application of international patent application number PCT/CN2016/073612 filed on Feb. 5, 2016, which claims priority to Chinese patent application number 201510368581.9 filed on Jun. 29, 2015. The disclosures of the aforementioned applications are hereby incorporated by reference in their entireties.

### TECHNICAL FIELD

Embodiments of the disclosure relate to the field of electronic device technologies, and in particular, to a thermal pad and an electronic device.

### BACKGROUND

Heat generated when a chip in an electronic device works generally needs to be dissipated to the outside by using a heat sink. From a microscopic perspective, contact interfaces of the chip and the heat sink are both rough, and a thermal pad needs to be made out of a thermal interface material to fill between the contact interfaces of the chip and the heat sink, to reduce contact thermal resistance. The thermal interface material generally includes thermally conductive silicone, a thermally conductive pad, thermal gel, a phase-change thermally conductive material, a thermally conductive double-sided tape, and the like. Thermal interface materials of different types with different coefficients of thermal conductivity may be used according to different application scenarios.

As a power density of a chip in an electronic device continuously increases, for heat dissipation of a high-power chip, because a problem of a partial hotspot occurs during packaging of the chip, and an existing thermal pad has a high coefficient of thermal conductivity only in a thickness direction, heat of the partial hotspot cannot be dissipated in time, and a service life of the chip is affected.

### SUMMARY

Embodiments of the disclosure provide a thermal pad and an electronic device, to effectively relieve a heat dissipation difficulty caused by a problem of a partial hotspot of a heat emitting component.

According to a first aspect, an embodiment of the disclosure provides a thermal pad configured to perform heat dissipation for a heat emitting component, where the thermal pad includes a first heat conducting layer and a second heat conducting layer, a first surface of the second heat conducting layer is in contact with a surface of the heat emitting component, and a second surface of the second heat conducting layer is in contact with a first surface of the first heat conducting layer; the first heat conducting layer is a heat conducting layer that can be compressed to deform, a heat conduction capability of the first heat conducting layer in a thickness direction of the first heat conducting layer is higher than a heat conduction capability of the first heat conducting layer in a plane (also referred to as planar herein) direction of the first heat conducting layer, and the thickness direction of the first heat conducting layer is perpendicular to the planar direction of the first heat conducting layer; and the second heat conducting layer is a heat conducting layer that cannot be compressed to deform, a heat conduction capability of the second heat conducting layer in a planar direction of the second heat conducting layer is higher than or equal to a heat conduction capability of the second heat conducting layer in a thickness direction of the second heat conducting layer, the heat conduction capability of the second heat conducting layer in the planar direction of the second heat conducting layer is higher than or equal to the heat conduction capability of the first heat conducting layer in the thickness direction of the first heat conducting layer, and the thickness direction of the second heat conducting layer is perpendicular to the planar direction of the second heat conducting layer.

With reference to the first aspect, in a first possible implementation manner of the first aspect, that the first heat conducting layer is a heat conducting layer that can be compressed to deform specifically refers to a ratio of compression and deformation of the first heat conducting layer under the action of first pressure is 5 percent (%) to 90%, where the first pressure ranges between 0 Newton (N) and 5000 N.

With reference to the first possible implementation manner of the first aspect, in a second possible implementation manner of the first aspect, that the second heat conducting layer is a heat conducting layer that cannot be compressed to deform specifically refers to a ratio of compression and deformation of the second heat conducting layer under the action of the first pressure is less than or equal to 5%.

With reference to the first aspect, the first possible implementation manner of the first aspect, or the second possible implementation manner of the first aspect, in a third possible implementation manner of the first aspect, a thickness of the first heat conducting layer is 0.2 mm to 5 mm, and a thickness of the second heat conducting layer is 0.1 mm to 5 mm.

With reference to the first aspect or any one of the first possible implementation manner of the first aspect to the third possible implementation manner of the first aspect, in a fourth possible implementation manner of the first aspect, the thermal pad further includes a third heat conducting layer, where the third heat conducting layer is disposed between the heat emitting component and the second heat conducting layer, a first surface of the third heat conducting layer is in contact with the surface of the heat emitting component, a second surface of the third heat conducting layer is in contact with the first surface of the second heat conducting layer, and the third heat conducting layer is configured to fill in a micro void on the surface of the heat emitting component.

With reference to the fourth possible implementation manner of the first aspect, in a fifth possible implementation manner of the first aspect, a thickness of the third heat conducting layer is less than or equal to 0.2 mm, and the third heat conducting layer is a prepreg or the third heat conducting layer is gel-like.

With reference to the first aspect or any one of the first to fifth possible implementation manners of the first aspect, in a sixth possible implementation manner of the first aspect, the first heat conducting layer includes an organic matrix and a heat conducting filler, and the heat conducting filler is orientated in the first heat conducting layer in the thickness direction of the first heat conducting layer.

With reference to the sixth possible implementation manner of the first aspect, in a seventh possible implementation manner of the first aspect, the heat conducting filler includes a sheet-like heat conducting filler or the heat conducting filler includes a fiber-like heat conducting filler; or the heat conducting filler includes a sheet-like heat conducting filler and a fiber-like heat conducting filler.

With reference to the first aspect or any one of the first to seventh possible implementation manners of the first aspect, in an eighth possible implementation manner of the first aspect, a material of the second heat conducting layer includes at least one of a metal or a graphite.

With reference to the first aspect or any one of the first to eighth possible implementation manners of the first aspect, in a ninth possible implementation manner of the first aspect, a second surface of the first heat conducting layer is in contact with a heat sink.

According to a second aspect, an embodiment of the disclosure provides an electronic device, including the thermal pad provided in the first aspect of the disclosure or the possible implementation manners of the first aspect and a heat emitting component, where a surface of the thermal pad is in contact with a surface of the heat emitting component; and the thermal pad is configured to perform heat dissipation processing on heat generated by the heat emitting component.

According to a third aspect, an embodiment of the disclosure provides a method for manufacturing a thermal pad, where the method includes providing a viscous organic composite; providing a second heat conducting layer, where the second heat conducting layer is a heat conducting layer that cannot be compressed to deform, a heat conduction capability of the second heat conducting layer in a planar direction of the second heat conducting layer is higher than or equal to a heat conduction capability of the second heat conducting layer in a thickness direction of the second heat conducting layer, and the thickness direction of the second heat conducting layer is perpendicular to the planar direction of the second heat conducting layer; coating the viscous organic composite on a surface of the second heat conducting layer; and performing solidification processing on the organic composite, so as to form a first heat conducting layer on the surface of the second heat conducting layer, where the first heat conducting layer is a heat conducting layer that can be compressed to deform, a heat conduction capability of the first heat conducting layer in a thickness direction of the first heat conducting layer is higher than a heat conduction capability of the first heat conducting layer in a planar direction of the first heat conducting layer, the heat conduction capability of the second heat conducting layer in the planar direction of the second heat conducting layer is higher than or equal to the heat conduction capability of the first heat conducting layer in the thickness direction of the first heat conducting layer, and the thickness direction of the first heat conducting layer is perpendicular to the planar direction of the first heat conducting layer.

According to a fourth aspect, an embodiment of the disclosure provides a method for manufacturing a thermal pad, where the method includes providing a viscous organic composite; performing solidification processing on the organic composite, so as to form a first heat conducting layer, where the first heat conducting layer is a heat conducting layer that can be compressed to deform, a heat conduction capability of the first heat conducting layer in a thickness direction of the first heat conducting layer is higher than a heat conduction capability of the first heat conducting layer in a planar direction of the first heat conducting layer, and the thickness direction of the first heat conducting layer is perpendicular to the planar direction of the first heat conducting layer; and providing a second heat conducting layer, and attaching a surface of the second heat conducting layer to a surface of the first heat conducting layer, so as to form the thermal pad, where the second heat conducting layer is a heat conducting layer that cannot be compressed to deform, a heat conduction capability of the second heat conducting layer in a planar direction of the second heat conducting layer is higher than or equal to the heat conduction capability of the first heat conducting layer in the thickness direction of the first heat conducting layer, the heat conduction capability of the second heat conducting layer in the planar direction of the second heat conducting layer is higher than or equal to a heat conduction capability of the second heat conducting layer in a thickness direction of the second heat conducting layer, and the thickness direction of the second heat conducting layer is perpendicular to the planar direction of the second heat conducting layer.

It can be known that the thermal pad provided in the embodiments of the disclosure includes a second heat conducting layer that is in contact with a surface of a heat emitting component, and a first heat conducting layer that is in contact with a surface of the second heat conducting layer. Because a heat conduction capability of the second heat conducting layer in a planar direction of the second heat conducting layer is higher than or equal to a heat conduction capability of the second heat conducting layer in a thickness direction of the second heat conducting layer, after the second heat conducting layer receives heat transferred by the heat emitting component, for the heat, a dissipation capability in the planar direction of the second heat conducting layer is higher than a conduction capability in the thickness direction of the second heat conducting layer, and because the heat conduction capability of the second heat conducting layer in the planar direction of the second heat conducting layer is higher than a heat conduction capability of the first heat conducting layer in a thickness direction of the first heat conducting layer, the second heat conducting layer can fully dissipate the heat in the planar direction of the second heat conducting layer, and then conduct the heat to the first heat conducting layer, thereby avoiding that when the heat emitting component partially emits excessive heat and causes an excessively high temperature, a partial hotspot appears on the second heat conducting layer that is in contact with the heat emitting component, and a device is damaged because heat of the partial hotspot cannot be conducted out in time. Then, because the heat conduction capability of the first heat conducting layer in the thickness direction of the first heat conducting layer is higher than a heat conduction capability of the first heat conducting layer in a planar direction of the first heat conducting layer, the first heat conducting layer can conduct the heat out in time. When heat dissipation processing is performed on a heat emitting component by using the thermal pad provided in the embodiments of the disclosure, a phenomenon that the heat emitting component of a device is damaged because the heat emitting component partially emits excessive heat and forms a partial hotspot, and the heat of the partial hotspot cannot be conducted out in time can be avoided.

### BRIEF DESCRIPTION OF DRAWINGS

To describe the technical solutions in the embodiments of the disclosure more clearly, the following briefly introduces the accompanying drawings required for describing the embodiments. The accompanying drawings in the following description show some embodiments of the disclosure, and a person of ordinary skill in the art may still derive other drawings from these accompanying drawings without creative efforts.

FIG. 1 is a schematic structural diagram of Embodiment 1 of a thermal pad according to the disclosure;

FIG. 2 is a schematic structural diagram of Embodiment 2 of a thermal pad according to the disclosure;

FIG. 3 is a schematic structural diagram of Embodiment 1 of a first heat conducting layer in a thermal pad according to the disclosure;

FIG. 4 is a schematic structural diagram of Embodiment 3 of a thermal pad according to the disclosure;

FIG. 5 is a schematic structural diagram of Embodiment 1 of an electronic device according to the disclosure;

FIG. 6 is a flowchart of Embodiment 1 of a method for manufacturing a thermal pad according to the disclosure; and

FIG. 7 is a flowchart of Embodiment 2 of a method for manufacturing a thermal pad according to the disclosure.

### DESCRIPTION OF EMBODIMENTS

To make the objectives, technical solutions, and advantages of the embodiments of the disclosure clearer, the following clearly describes the technical solutions in the embodiments of the disclosure with reference to the accompanying drawings in the embodiments of the disclosure. The described embodiments are some but not all of the embodiments of the disclosure. All other embodiments obtained by a person of ordinary skill in the art based on the embodiments of the disclosure without creative efforts shall fall within the protection scope of the disclosure.

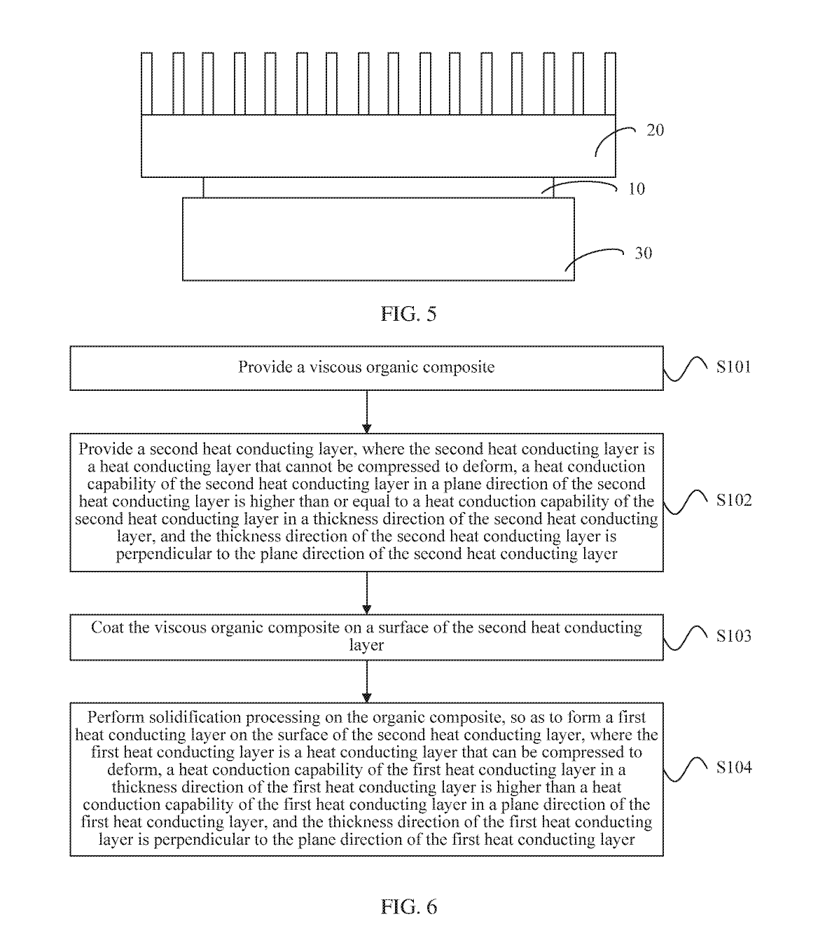

FIG. 1 is a schematic structural diagram of Embodiment 1 of a thermal pad according to the disclosure. As shown in FIG. 1, the thermal pad in this embodiment is configured to perform heat dissipation for a heat emitting component 30 (See FIG. 5), and includes a first heat conducting layer 11 and a second heat conducting layer 12. A first surface of the second heat conducting layer 12 is in contact with a surface of the heat emitting component 30 (FIG. 5), and a second surface of the second heat conducting layer 12 is in contact with a first surface of the first heat conducting layer 11. The first heat conducting layer 11 is a heat conducting layer that can be compressed to deform, and a heat conduction capability of the first heat conducting layer 11 in a thickness direction of the first heat conducting layer 11 is higher than a heat conduction capability of the first heat conducting layer 11 in a planar direction of the first heat conducting layer 11. It should be noted that the thickness direction of the first heat conducting layer is perpendicular to the planar direction of the first heat conducting layer. Because the heat conduction capability of the first heat conducting layer 11 in the thickness direction of the first heat conducting layer 11 is higher than the heat conduction capability of the first heat conducting layer 11 in the planar direction of the first heat conducting layer 11, the thermal pad in this embodiment has a high heat conduction capability in a thickness direction of the thermal pad. In addition, the second heat conducting layer 12 in this embodiment is a heat conducting layer that cannot be compressed to deform, a heat conduction capability of the second heat conducting layer 12 in a planar direction of the second heat conducting layer 12 is higher than or equal to a heat conduction capability of the second heat conducting layer 12 in a thickness direction of the second heat conducting layer 12, and the heat conduction capability of the second heat conducting layer 12 in the planar direction of the second heat conducting layer 12 is higher than or equal to the heat conduction capability of the first heat conducting layer 11 in the thickness direction of the first heat conducting layer 11. It should be noted that the thickness direction of the second heat conducting layer 12 is perpendicular to the planar direction of the second heat conducting layer 12. Therefore, the thermal pad in this embodiment has a higher heat conduction capability in a planar direction of the thermal pad. Thus, the thermal pad in this embodiment not only has a high heat conduction capability in the thickness direction, but also has a higher heat conduction capability in the planar direction.

The first heat conducting layer 11 can be compressed to deform to a ratio of compression and deformation of the first heat conducting layer 11 under the action of first pressure is 5% to 90%, where the first pressure ranges between 0 N and 5000 N. Preferably, the first pressure ranges between 0 N to 200 N.

The second heat conducting layer 12 is a heat conducting layer that cannot be compressed to deform to a ratio of compression and deformation of the second heat conducting layer 12 under the action of the first pressure is 0% to 5%.

Optionally, a thickness of the first heat conducting layer 11 is 0.2 mm to 5 mm, and a thickness of the second heat conducting layer 12 is 0.1 millimeter (mm) to 5 mm.

The thermal pad in this embodiment includes a second heat conducting layer 12 that is in contact with a surface of a heat emitting component 30 (FIG. 5), and a first heat conducting layer 11 that is in contact with a surface of the second heat conducting layer 12. Because a heat conduction capability of the second heat conducting layer 12 in a planar direction of the second heat conducting layer 12 is higher than or equal to a heat conduction capability of the second heat conducting layer 12 in a thickness direction of the second heat conducting layer 12, after the second heat conducting layer 12 receives heat transferred by the heat emitting component 30 (FIG. 5), for the heat, a dissipation capability in the planar direction of the second heat conducting layer 12 is higher than a conduction capability in the thickness direction of the second heat conducting layer 12, and because the heat conduction capability of the second heat conducting layer 12 in the planar direction of the second heat conducting layer 12 is higher than a heat conduction capability of the first heat conducting layer 11 in a thickness direction of the first heat conducting layer 11, the second heat conducting layer 12 can fully dissipate the heat in the planar direction of the second heat conducting layer 12, and then conduct the heat to the first heat conducting layer 11, thereby avoiding that when the heat emitting component 30 (FIG. 5) partially emits excessive heat and causes an excessively high temperature, a partial hotspot appears on the second heat conducting layer 12 that is in contact with the heat emitting component 30 (FIG. 5), and a device is damaged because heat of the partial hotspot cannot be conducted out in time. Then, because the heat conduction capability of the first heat conducting layer 11 in the thickness direction of the first heat conducting layer 11 is higher than a heat conduction capability of the first heat conducting layer 11 in a planar direction of the first heat conducting layer 11, the first heat conducting layer 11 can conduct the heat out in time. When heat dissipation processing is performed on a heat emitting component 30 (FIG. 5) by using the thermal pad provided in this embodiment of the disclosure, a phenomenon that a device is damaged because the heat emitting component 30 (FIG. 5) partially emits excessive heat and forms a partial hotspot, and the heat of the partial hotspot cannot be conducted out in time can be avoided.

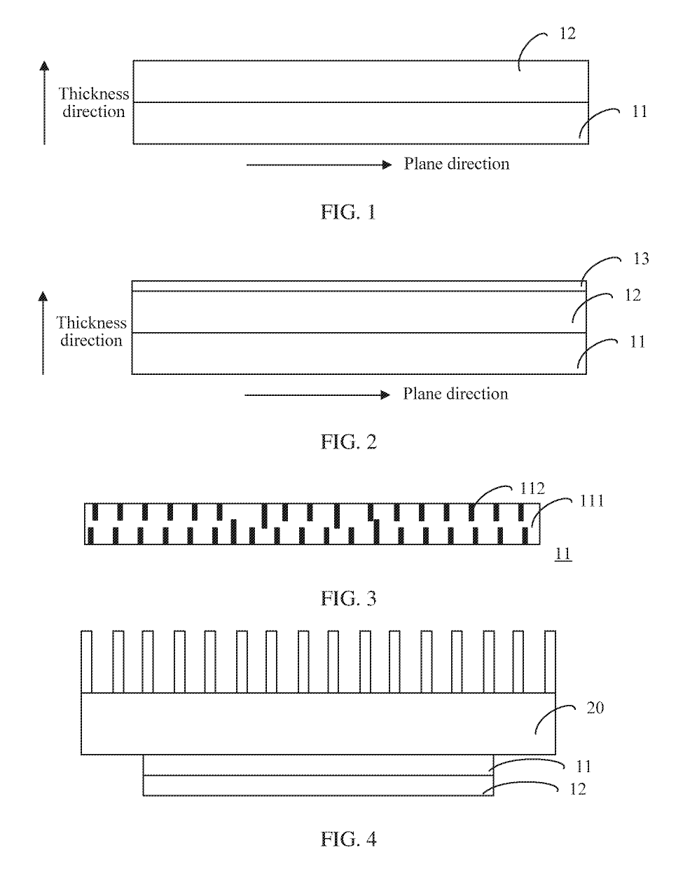

FIG. 2 is a schematic structural diagram of Embodiment 2 of a thermal pad according to the disclosure. As shown in FIG. 2, based on Embodiment 1 of the disclosure, the thermal pad in this embodiment may further include a third heat conducting layer 13, where the third heat conducting layer 13 is disposed between the heat emitting component 30 (See FIG. 5) and the second heat conducting layer 12, a first surface of the third heat conducting layer 13 is in contact with the surface of the heat emitting component 30, a second surface of the third heat conducting layer 13 is in contact with the first surface of the second heat conducting layer 12, the third heat conducting layer 13 is configured to fill in a micro void on the surface of the heat emitting component 30 and a thickness of the third heat conducting layer 13 is greater than 0 and is less than the thickness of the first heat conducting layer 11. Therefore, when the thermal pad in this embodiment is disposed between the heat emitting component 30 and a heat sink 20 (See FIG. 5), the third heat conducting layer 13 is in contact with the heat emitting component. 30, and the third heat conducting layer 13 can reduce contact thermal resistance between the second heat conducting layer 12 and the heat emitting component 30, which further improves a heat dissipation effect.

Based on Embodiment 2 of the disclosure, optionally, the thickness of the third heat conducting layer 13 is less than or equal to 0.2 mm. The third heat conducting layer 13 is made relatively thin, so as to reduce the contact thermal resistance. In addition, the third heat conducting layer 13 is a prepreg or the third heat conducting layer 13 is gel-like.

Based on Embodiment 1 or 2 in the disclosure, optionally, as shown in FIG. 3, the first heat conducting layer 11 includes an organic matrix 111 and a heat conducting filler 112, and the heat conducting filler 112 is orientated in the first heat conducting layer 11 in the thickness direction of the first heat conducting layer 11. Because the heat conducting filler 112 is orientated in the first heat conducting layer 11 in the thickness direction of the first heat conducting layer 11, the heat conduction capability of the first heat conducting layer 11 in the thickness direction of the first heat conducting layer 11 is higher than the heat conduction capability of the first heat conducting layer 11 in the planar direction of the first heat conducting layer 11. Optionally, the organic matrix 111 may include ethylene-containing organopolysiloxane and hydride terminated polydimethylsiloxane-containing organopolysiloxane. The heat conducting filler 112 includes a sheet-like heat conducting filler, or the heat conducting filler 112 includes a fiber-like heat conducting filler, or the heat conducting filler 112 includes a sheet-like heat conducting filler and a fiber-like heat conducting filler. For example, the heat conducting filler 112 may include spherical alumina particles (having a particle size of 2 micrometer (μm) to 50 μm) and pitch-based carbon fibers (having an axial length of 60 μm to 180 μm and an axial diameter of 5 μm to 15 μm), or the heat conducting filler 112 may include spherical alumina particles (having a particle size of 2 μm to 50 μm) and sheet-like boron nitride (having a particle size of 5 μm to 15 μm).

Optionally, the heat conducting filler 112 is a heat conducting fiber, and the heat conducting fiber may be a carbon fiber or a carbon nanotube.

Optionally, a material of the second heat conducting layer 12 includes a material that has high thermal conductivity in a planar direction, such as metal, or graphite, or metal and graphite, or a graphene film, or a carbon nanotube film. Optionally, the metal may be copper. A coefficient of thermal conductivity of the second heat conducting layer 12 in the planar direction in this embodiment is hundreds of Watts per meter Kelvin (W/mk), and even thousands of W/mk, which can effectively reduce planar extension thermal resistance.

FIG. 4 is a schematic structural diagram of Embodiment 3 of a thermal pad according to the disclosure. As shown in FIG. 4, based on the foregoing thermal pad embodiments in the disclosure, in the thermal pad in this embodiment, further, the second surface of the first heat conducting layer 11 of the thermal pad is in contact with a heat sink 20.

FIG. 5 is a schematic structural diagram of Embodiment 1 of an electronic device according to the disclosure. As shown in FIG. 5, a heat dissipation apparatus in this embodiment may include a thermal pad 10 and a heat emitting component 30, where the thermal pad 10 is the thermal pad provided in the foregoing thermal pad embodiments in the disclosure, and the implementation principles and technical effects thereof are similar, and are not described herein again. It should be noted that, in this embodiment, a surface of the thermal pad 10 is in contact with a surface of the heat emitting component 30, and the thermal pad 10 performs heat dissipation processing on heat generated by the heat emitting component 30. If the thermal pad 10 is further in contact with a heat sink 20, a surface of a first heat conducting layer of the thermal pad 10 is in contact with the heat sink 20.

FIG. 6 is a flowchart of Embodiment 1 of a method for manufacturing a thermal pad according to the disclosure. As shown in FIG. 6, the method in this embodiment may include the following steps.

S101: Provide a viscous organic composite.

S102: Provide a second heat conducting layer, where the second heat conducting layer is a heat conducting layer that cannot be compressed to deform, a heat conduction capability of the second heat conducting layer in a planar direction of the second heat conducting layer is higher than or equal to a heat conduction capability of the second heat conducting layer in a thickness direction of the second heat conducting layer, and the thickness direction of the second heat conducting layer is perpendicular to the planar direction of the second heat conducting layer.

For example, the second heat conducting layer is a graphite sheet whose thickness is 0.9 mm, 0.5 mm, or 1 mm.

S103: Coat the viscous organic composite on a surface of the second heat conducting layer.

S104: Perform solidification processing on the organic composite, so as to form a first heat conducting layer on the surface of the second heat conducting layer, where the first heat conducting layer is a heat conducting layer that can be compressed to deform, a heat conduction capability of the first heat conducting layer in a thickness direction of the first heat conducting layer is higher than a heat conduction capability of the first heat conducting layer in a planar direction of the first heat conducting layer, and the thickness direction of the first heat conducting layer is perpendicular to the planar direction of the first heat conducting layer.

In an implementation manner of this embodiment, a viscous organic composite is provided, where the organic composite may include a heat conducting filler. For example, ethylene-containing organopolysiloxane, hydride terminated polydimethylsiloxane-containing organopolysiloxane, spherical alumina particles (having a particle size of 2 μm to 50 μm), and pitch-based carbon fibers (having an axial length of 60 μm to 180 μm and an axial diameter of 5 μpm to 15 μm) are mixed evenly according to a particular proportion (18:18:34:30) (of percents in volume), and are stirred to disperse into the viscous organic composite; or ethylene-containing organopolysiloxane, hydride terminated polydimethylsiloxane-containing organopolysiloxane, spherical alumina particles (having a particle size of 2 μm to 50 μm), and sheet-like boron nitride (having a particle size of 5 μm to 15 μm) are mixed evenly according to a particular proportion (50:50:80:150) (of percents in weight), and are stirred to disperse into the viscous organic composite; or ethylene-containing organopolysiloxane, hydride terminated polydimethylsiloxane-containing organopolysiloxane, spherical alumina particles (having a particle size of 2 μm to 50 μm), sheet-like boron nitride (having a particle size of 5 μm to 15 μm), and nanographene sheets (a thickness is 0.4 nm to 4 nm and a length is 5 μm to 20 μm) are mixed evenly according to a particular proportion (50:50:80:60:1.5) (of percents in weight), and. are stirred to disperse into the viscous organic composite.

Then, the viscous organic composite provided in step S101 is coated on a surface of a second heat conducting layer provided in step S102. Then, the heat conducting filler in the organic composite is orientated, and the organic composite is solidified. The organic composite forms a first heat conducting layer after the orientation processing and the solidification processing. Therefore, the first heat conducting layer is formed on the second heat conducting layer. In addition, the heat conducting filler after the orientation processing is orientated in a thickness direction of the first heat conducting layer. In this way, a heat conduction capability of the formed first heat conducting layer in the thickness direction of the first heat conducting layer is higher than a heat conduction capability of the first heat conducting layer in a planar direction of the first heat conducting layer. The orientation processing may be magnetic field orientation processing, electric field orientation processing, or stress orientation processing.

For example, the second heat conducting layer may be first placed in an orientation mold, the viscous organic composite is then poured on a surface of the second heat conducting layer in the orientation mold, and a magnetic field or an electric field is applied to the orientation mold, so as to implement magnetic field orientation processing or electric field orientation processing on the heat conducting filler in the organic composite, or stress is applied so as to implement stress orientation processing on the heat conducting filler in the organic composite, so that the heat conducting filler is orientated in a direction perpendicular to the planar direction of the second heat conducting layer; and the organic composite is heated and solidified in a heating furnace at 100 degree Celsius (° C.) to 120° C. for four hours to six hours to form a shape, so as to form the first heat conducting layer.

In this embodiment, in the thermal pad obtained in the foregoing manner, because a heat conduction capability of a second heat conducting layer in a planar direction of the second heat conducting layer is higher than or equal to a heat conduction capability of the second heat conducting layer in a thickness direction of the second heat conducting layer, after the second heat conducting layer receives heat transferred by a heat emitting component, for the heat, a dissipation capability in the planar direction of the second heat conducting layer is higher than a conduction capability in the thickness direction of the second heat conducting layer, and because the heat conduction capability of the second heat conducting layer in the planar direction of the second heat conducting layer is higher than a heat conduction capability of a first heat conducting layer in a thickness direction of the first heat conducting layer, the second heat conducting layer can fully dissipate the heat in the planar direction of the second heat conducting layer, and then conduct the heat to the first heat conducting layer, thereby avoiding that when the heat emitting component partially emits excessive heat and causes an excessively high temperature, a partial hotspot, appears on the second heat conducting layer that is in contact with the heat emitting component, and a device is damaged because heat of the partial hotspot cannot be conducted out in time. Then, because the heat conduction capability of the first heat conducting layer in the thickness direction of the first heat conducting layer is higher than a heat conduction capability of the first heat conducting layer in a planar direction of the first heat conducting layer, the first heat conducting layer can conduct the heat out in time. When heat dissipation processing is performed on a heat emitting component by using the thermal pad provided in this embodiment of the disclosure, a phenomenon that a device is damaged because the heat emitting component partially emits excessive heat and forms a partial hotspot, and the heat of the partial hotspot cannot be conducted out in time can be avoided.

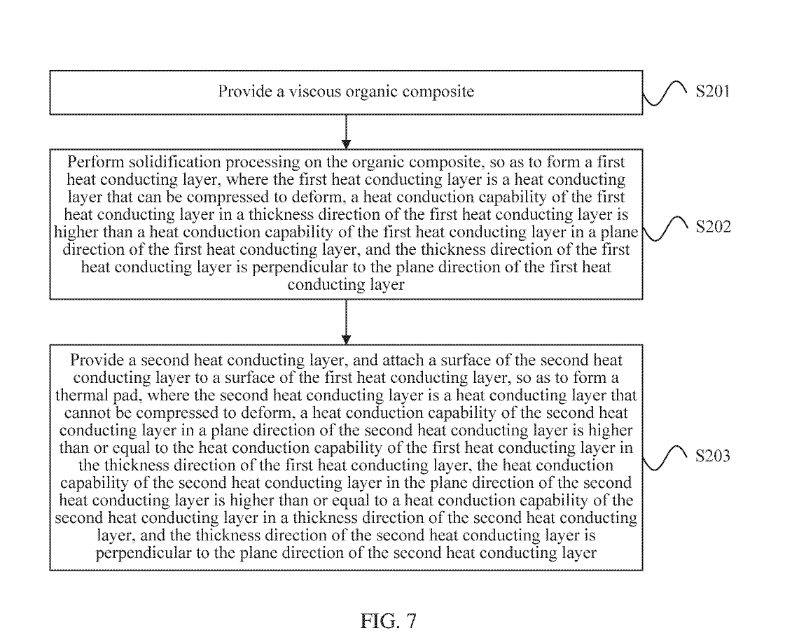

FIG. 7 is a flowchart of Embodiment 2 of a method for manufacturing a thermal pad according to the disclosure. As shown in FIG. 7, the method in this embodiment may include the following steps.

S201: Provide a viscous organic composite.

S202: Perform solidification processing on the organic composite, so as to form a first heat conducting layer, where the first heat conducting layer is a heat conducting layer that can be compressed to deform, a heat conduction capability of the first heat conducting layer in a thickness direction of the first heat conducting layer is higher than a heat conduction capability of the first heat conducting layer in a planar direction of the first heat conducting layer, and the thickness direction of the first heat conducting layer is perpendicular to the planar direction of the first heat conducting layer.

S203: Provide a second heat conducting layer, and attach a surface of the second heat conducting layer to a surface of the first heat conducting layer, so as to form the thermal pad, where the second heat conducting layer is a heat conducting layer that cannot be compressed to deform, a heat conduction capability of the second heat conducting layer in a planar direction of the second heat conducting layer is higher than or equal to the heat conduction capability of the first heat conducting layer in the thickness direction of the first heat conducting layer, the heat conduction capability of the second heat conducting layer in the planar direction of the second heat conducting layer is higher than or equal to a heat conduction capability of the second heat conducting layer in a thickness direction of the second heat conducting layer, the thickness direction of the second heat conducting layer is perpendicular to the planar direction of the second heat conducting layer.

In an implementation manner of this embodiment, a viscous organic composite is provided, where the organic composite may include a heat conducting filler. For example, ethylene-containing organopolysiloxane, hydride terminated polydimethylsiloxane-containing organopolysiloxane, spherical alumina particles (having a particle size of 2 μm to 50 μm), and. pitch-based carbon fibers (having an axial length of 60 μm to 180 μm and an axial diameter of 5 μm to 15 μm) are mixed evenly according to a particular proportion (18:18:34:30) (of percents in volume), and are stirred to disperse into the viscous organic composite.; or ethylene-containing organopolysiloxane, hydride terminated polydimethylsiloxane-containing organopolysiloxane, spherical alumina particles (having a particle size of 2 μm to 50 μm), and sheet-like boron nitride (having a particle size of 5 μm to 1.5 μm) are mixed evenly according to a particular proportion (50:50:80:150) (of percents in weight), and are stirred to disperse into the viscous organic composite; or ethylene-containing organopolysiloxane, hydride terminated polydimethylsiloxane-containing organopolysiloxane, spherical alumina particles (having a particle size of 2 μm to 50 μm), sheet-like boron nitride (having a particle size of 5 μm to 15 μm), and nanographene sheets (a thickness is 0.4 nm to 4 nm and a length is 5 μm to 20 μm) are mixed evenly according to a particular proportion (50:50:80:60:1.5) (of percents in weight), and are stirred to disperse into the viscous organic composite.

Then, the organic composite is solidified, so as to form a first heat conducting layer, and the heat conducting filler is orientated in a thickness direction of the first heat conducting layer. In this way, a heat conduction capability of the formed first heat conducting layer in the thickness direction of the first heat conducting layer is higher than a heat conduction capability of the first heat conducting layer in a planar direction of the first heat conducting layer. The orientation processing may be magnetic field orientation processing, electric field orientation processing, or stress orientation processing.

For example, the viscous organic composite is poured into an orientation mold, and a magnetic field or an electric field is applied to the orientation mold, so as to implement magnetic field orientation processing or electric field orientation processing on the heat conducting filler in the organic composite, or stress is applied so as to implement stress orientation processing on the heat conducting filler in the organic composite, so that the heat conducting filler is orientated in a direction perpendicular to the thickness direction of the first heat conducting layer; and the organic composite is heated and solidified in a heating furnace at 100° C. to 120° C. for four hours to six hours to form a shape, so as to form the first heat conducting layer.

For example, the second heat conducting layer is a graphite sheet whose thickness is 0.9 mm, 0.5 mm, or 1 mm. After step S202, a surface of the second heat conducting layer is attached to a surface of the first heat conducting layer on which orientation processing and solidification processing are performed, so as to form the thermal pad.

For example, a surface of the second heat conducting layer may be coated with a heat conducting pressure-sensitive adhesive layer whose thickness is 10 μm, a separation film is added, and a surface of the first heat conducting layer is recombined with the second heat conducting layer whose surface has a heat conduction pressure-sensitive adhesive layer, so that the second heat conducting layer is attached to the first heat conducting layer, to form the thermal pad.

In this embodiment, in the thermal pad obtained in the foregoing manner, because a heat conduction capability of a second heat conducting layer in a planar direction of the second heat conducting layer is higher than or equal to a heat conduction capability of the second heat conducting layer in a thickness direction of the second heat conducting layer, after the second heat conducting layer receives heat transferred by a heat emitting component, for the heat, a dissipation capability in the planar direction of the second heat conducting layer is higher than a conduction capability in the thickness direction of the second heat conducting layer, and because the heat conduction capability of the second heat conducting layer in the planar direction of the second heat conducting layer is higher than a heat conduction capability of a first heat conducting layer in a thickness direction of the first heat conducting layer, the second heat conducting layer can fully dissipate the heat in the planar direction of the second heat conducting layer, and then conduct the heat to the first heat conducting layer, thereby avoiding that when the heat emitting component partially emits excessive heat and causes an excessively high temperature, a partial hotspot appears on the second heat conducting layer that is in contact with the heat emitting component, and a device is damaged because heat of the partial hotspot cannot be conducted out in time. Then, because the heat conduction capability of the first heat conducting layer in the thickness direction of the first heat conducting layer is higher than a heat conduction capability of the first heat conducting layer in a planar direction of the first heat conducting layer, the first heat conducting layer can conduct the heat out in time. When heat dissipation processing is performed on a heat emitting component by using the thermal pad provided in this embodiment of the disclosure, a phenomenon that a device is damaged because the heat emitting component partially emits excessive heat and forms a partial hotspot, and the heat of the partial hotspot cannot be conducted out in time can be avoided.

Optionally, based on Method Embodiment 1 or 2 in the disclosure, the method further includes forming a third heat conducting layer on the other surface opposite the surface, which is combined with the first heat conducting layer, of the second heat conducting layer, where the third heat conducting layer is configured to fill in a micro void on the surface of the heat, emitting component. For example, a layer of thermally conductive silicone whose thickness is 0.05 mm to 0.15 mm is applied to the surface of the second heat, conducting layer by using a printing process. The thermal pad obtained by using the method in this embodiment further includes the foregoing third heat conducting layer, which can reduce contact thermal resistance of the thermal pad.

Finally, it should be noted that the foregoing embodiments are merely intended for describing the technical solutions of the disclosure, but not for limiting the disclosure. Although the disclosure is described in detail with reference to the foregoing embodiments, persons of ordinary skill in the art should understand that they may still make modifications to the technical solutions described in the foregoing embodiments or make equivalent replacements to some or all technical features thereof, without departing from the scope of the technical solutions of the embodiments of the disclosure.

What is claimed is:

1. A thermal pad for a heat emitting component, comprising:
a first heat conducting layer comprising a first surface and a second surface, wherein the first heat conducting layer is deformable through compression, wherein a first heat conduction capability in a first thickness direction of the first heat conducting layer is greater than a second heat conduction capability in a plane direction of the first heat conducting layer, and wherein the first thickness direction of the first heat conducting layer is perpendicular to the first planar direction of the first heat conducting layer; and
a second heat conducting layer comprising a third surface and a fourth surface, wherein the second heat conducting layer is not deformable through compression, wherein the third surface of the second heat conducting layer is configured to contact an exterior surface of the heat emitting component, wherein the fourth surface of the second heat conducting layer is in contact with the first surface of the first heat conducting layer, wherein a third heat conduction capability in a second plane direction of the second heat conducting layer is greater than or equal to a fourth heat conduction capability in a second thickness direction of the second heat conducting layer, wherein the third heat conduction capability is greater than or equal to the first heat conduction capability, and wherein the second thickness direction of the second heat conducting layer is perpendicular to the second plane direction of the second heat conducting layer.

2. The thermal pad according to claim 1, wherein the first heat conducting layer is deformable under a first pressure with a ratio of compression to deformation from 5% to 90%, and
wherein the first pressure is in a range between 0 Newton (N) and 5000 N.

3. The thermal pad according to claim 2, wherein the second heat conducting layer is not deformable under the first pressure, and wherein a ratio of compression to deformation of the second heat conducting layer is less than or equal to 5%.

4. The thermal pad according to claim 1, wherein a first thickness of the first heat conducting layer is 0.2 millimeter (mm) to 5 mm and a second thickness of the second heat conducting layer is 0.1 mm to 5 mm.

5. The thermal pad according to claim 1, further comprising a third heat conducting layer configured to be disposed between the heat emitting component and the second heat conducting layer, wherein a fifth surface of the third heat conducting layer is in contact with the exterior surface of the heat emitting component, wherein a sixth surface of the third heat conducting layer is in contact with the third surface of the second heat conducting layer, and wherein the third heat conducting layer is configured to fill in a micro void on the exterior surface of the heat emitting component.

6. The thermal pad according to claim 5, wherein a third thickness of the third heat conducting layer is less than or equal to 0.2 mm, and wherein the third heat conducting layer is either a prepreg or gel-like.

7. The thermal pad according to claim 1, wherein the first heat conducting layer further comprises an organic matrix and a heat conducting filler, and wherein the heat conducting filler is oriented in the first thickness direction of the first heat conducting layer.

8. The thermal pad according to claim 7, wherein the heat conducting filler comprises a sheet-like heat conducting filler.

9. The thermal pad according to claim 1, wherein a material of the second heat conducting layer comprises metal, graphite, or a combination of metal and graphite.

10. The thermal pad according to claim 1, wherein the second surface of the first heat conducting layer is in contact with a heat sink.

11. An electronic device, comprising:
a thermal pad; and
a heat emitting component, wherein a surface of the thermal pad is in contact with an exterior surface of the heat emitting component, wherein the thermal pad is configured to dissipate heat generated by the heat emitting component, and
wherein the thermal pad comprises:
a first heat conducting layer comprising a first surface and a second surface, wherein the first heat conducting layer is deformable through compression, wherein a first heat conduction capability in a first thickness direction of the first heat conducting layer is greater than a second heat conduction capability in a first planar direction of the first heat conducting layer, and wherein the first thickness direction of the first heat conducting layer is perpendicular to the first plane direction of the first heat conducting layer; and
a second heat conducting layer comprising a third surface and a fourth surface, wherein the third surface of the second heat conducting layer is in contact with the exterior surface of the heat emitting component, wherein the fourth surface of the second heat conducting layer is in contact with the first surface of the first heat conducting layer, wherein the second heat conducting layer is not deformable through compression, wherein a third heat conduction capability in a second plane direction of the second heat conducting layer is greater than or equal to a fourth heat conduction capability in a. second thickness direction of the second heat conducting layer, wherein the third heat conduction capability in the second plane direction of the second heat conducting layer is greater than or equal to the first heat conduction capability in the first thickness direction of the first heat conducting layer, and wherein the second thickness direction of the second heat conducting layer is perpendicular to the second plane direction of the second heat conducting layer.

12. The electronic device according to claim 11, wherein the first heat conducting layer is deformable under a first pressure with a ratio of compression to deformation of about 5% to 90%, and wherein the first pressure is in a range between 0 Newton (N) and 5000 N.

13. The electronic device according to claim 12, wherein the second heat conducting layer is not deformable under the first pressure, wherein a ratio of compression to deformation of the second heat conducting layer is less than or equal to 5%.

14. The electronic device according to claim 11, wherein a first thickness of the first heat conducting layer is 0.2 millimeter (mm) to 5 mm and a second thickness of the second heat conducting layer is 0.1 mm to 5 mm.

15. The electronic device according to claim 11, further comprising a third heat conducting layer comprising a fifth surface and a sixth surface, wherein the third heat conducting layer is configured to be disposed between the heat emitting component and the second heat conducting layer, wherein the fifth surface of the third heat conducting layer is in contact with the exterior surface of the heat emitting component, wherein the sixth surface of the third heat conducting layer is in contact with the third surface of the second heat conducting layer, and wherein the third heat conducting layer is configured to fill in a micro void on the exterior surface of the heat emitting component.

16. The electronic device according to claim 15, wherein a third thickness of the third heat conducting layer is less than or equal to 0.2 mm, and wherein the third heat conducting layer is either a prepreg or gel-like.

17. The electronic device according to claim 11, wherein the first heat conducting layer further comprises an organic matrix and a heat conducting filler, and wherein the heat conducting filler is orientated in the third thickness direction of the first heat conducting layer.

18. The thermal pad according to claim 7, wherein the heat conducting filler comprises a fiber-like heat conducting filler.

19. The thermal pad according to claim 7, wherein the heat conducting filler comprises both a sheet-like heat conducting filler and a fiber-like heat conducting filler.
